(19) United States
(12) Patent Application Publication
(10) Pub. No.: US 2023/0015476 A1
(43) Pub. Date: Jan. 19, 2023

(54) Semiconductor Device and Procedures to its Manufacture

(71) Applicant: OSRAM Opto Semiconductors GmbH, Regensburg (DE)

(72) Inventors: Stefan Rass, Regensburg (DE); Bjoern Hoxhold, Sinzing Viehhausen (DE); Andreas Waldschik, Wolmirstedt (DE); Andreas Dobner, Wenzenbach (DE); Hermann Nuss, Regensburg (DE)

(21) Appl. No.: 17/757,726

(22) PCT Filed: Dec. 8, 2020
(86) PCT No.: PCT/EP2020/085052

§ 371 Date: Jun. 20, 2022

(30) Foreign Application Priority Data
Dec. 20, 2019 (DE) 10 2019 220 378.7

(51) Int. Cl. H01L 33/62; H01L 25/075

(52) U.S. Cl. CPC H01L 33/62; H01L 25/0753; H01L 2933/0066

(57) ABSTRACT

In an embodiment a semiconductor component includes a carrier, at least one semiconductor chip arranged on the carrier, the semiconductor chip having at least one first electrical contact at a main surface of the semiconductor chip facing away from the carrier, an electrically insulating layer arranged on the carrier and at least one electrical connection layer led by the electrically insulating layer to the first electrical contact, wherein the electrically insulating layer includes a photopatternable material.

This patent application is a national phase filing under section 371 of PCT/EP2020/085052, filed Dec. 8, 2020, which claims the priority of German patent application 10 2019 220 378.7, filed Dec. 20, 2019, each of which is incorporated herein by reference in its entirety.

### TECHNICAL FIELD

The present application relates to a semiconductor component and to a method for producing same. The semiconductor component can be in particular an optoelectronic semiconductor component such as, for example, an LED or an LED display.

### BACKGROUND

An object to be achieved consists in specifying a semiconductor component and a method for producing same, the semiconductor component being distinguished by a high reliability and the method being distinguished by a low production outlay.

### SUMMARY

These objects are achieved by means of a semiconductor component and a method for producing same as claimed in the independent patent claims. The dependent claims relate to advantageous configurations and developments of the invention.

In accordance with at least one embodiment, the semiconductor component comprises a carrier and at least one semiconductor chip arranged on the carrier. The semiconductor component can be in particular an optoelectronic component, for example an LED, an LED module or an LED display. The at least one semiconductor chip can be in particular a light emitting diode chip. In one preferred configuration, a plurality of semiconductor chips are arranged on the carrier.

The at least one semiconductor chip has a first electrical contact at a main surface facing away from the carrier. A second electrical contact of the semiconductor chip can be arranged for example at a main surface of the semiconductor chip facing the carrier. Alternatively, both the first electrical contact and the second electrical contact of the semiconductor chip can be arranged at the main surface of the semiconductor chip facing away from the carrier.

In accordance with at least one embodiment, the semiconductor component comprises an electrically insulating layer arranged on the carrier. Here and hereinafter, the fact that one layer or one element is arranged or applied “on” or “over” another layer or another element can mean that said one layer or said one element is arranged directly in direct mechanical and/or electrical contact on the other layer or other element. Furthermore, it can also mean that said one layer or said one element is arranged indirectly on or over the other layer or the other element. In this case, further layers and/or elements can then be arranged between said one layer and the other layer or between said one element and the other element.

The electrically insulating layer can cover in particular the sidewalls of the at least one semiconductor chip. The thickness of the electrically insulating layer is preferably substantially equal to the height of the at least one semiconductor chip, for example with a tolerance of a maximum of 5% or a maximum of 10%. The electrically insulating layer can terminate in particular substantially flush with the main surface of the semiconductor chip which faces away from the carrier and at which the first electrical contact is arranged. The electrically insulating layer preferably comprises a plastics material.

In accordance with at least one embodiment, the semiconductor component comprises at least one electrical connection layer which is led to the first electrical contact by way of the electrically insulating layer. The electrically insulating layer insulates the electrical connection layer in particular from the sidewalls of the semiconductor chip and thus avoids a short circuit. The electrical connection layer is preferably applied to the electrically insulating layer by a coating method, for example by an electrolytic coating method. The electrical connection layer comprises for example a metal, in particular copper, or a metal alloy.

In accordance with at least one embodiment, the electrically insulating layer comprises a photopatternable material.

This makes it possible to produce openings in the electrically insulating layer, for example in order to produce contact feedthroughs, by means of photolithography, i.e. by exposing and subsequently removing an exposed or non-exposed region of the electrically insulating layer. By means of photolithography, the electrically insulating layer can be produced with high positioning accuracy of less than ±10 μm, for example.

The photopatternable electrically insulating layer can be applied to envisaged regions of the carrier in a targeted manner in order for example to insulate the sidewalls of the semiconductor chip and to enable the application of the electrical connection layer for producing a wire-free contacting. The semiconductor component has no bond wires, in particular; rather, the contacting of the at least one semiconductor chip at the main surface facing away from the carrier is effected by way of the electrical connection layer. Such a contacting is distinguished by a small height and is also referred to as planar contacting.

The use of a photopatternable layer as an electrically insulating layer has the advantage, in particular, that the production of the electrically insulating layer by means of a molding method, in particular by means of film assisted molding (FAM), is avoided in the case of the semiconductor component. Use of a molding method involves the risk of electrically insulating material reaching the surface of the semiconductor chip in an undesired manner. This can result in light losses or even in open electrical contacts. In the case of molding methods, material residues, for example burrs, that have arisen in an undesired manner generally have to be removed in an additional process (deflashing). However, this process involves the risk of damage to the surface of the semiconductor chip. In the case of the semiconductor chip described herein, the process-dictated risks of the molding process mentioned above are advantageously avoided by virtue of a photopatternable material being used and molding not being used.

In accordance with at least one embodiment, the photopatternable material is a flowable material. This has the advantage that the electrically insulating layer can be applied in a simple manner for example by means of spray coating and subsequently be photolithographically patterned. In comparison with the production of the electrically insulating layer by means of molding, height differences between semiconductor chips when applying the electrically insulating layer are unproblematic.

In accordance with at least one embodiment, the at least one electrical connection layer is led from a plane of the carrier to the first electrical contact by way of the electrically insulating layer. By way of example, the first electrical contact is connected to a connection contact on the plane of the carrier by way of the electrical connection layer. For example, the carrier can have at least one conductor track, wherein the at least one electrical connection layer is led from the conductor track to the first electrical contact by way of the electrically insulating layer. The electrically insulating layer can have the form of a ramp that overcomes the height difference between the plane of the carrier and the plane of the first electrical contact.

In accordance with at least one embodiment, an opening is formed in the electrically insulating layer, wherein a part of the electrical connection layer is led by way of sidewalls of the opening. The opening can lead in particular from a plane of the carrier to the plane of the first electrical contact. The semiconductor component can have in particular a first contacting plane at the level of the first electrical contact of the at least one semiconductor chip and a second contacting plane at the level of the carrier. In this case, the electrical connection layer led by way of the sidewalls of the opening can form a through contact between the first contacting plane and the second contacting plane.

In accordance with at least one embodiment, the opening has a width of at least 10 μm, preferably of at least 50 μm, and particularly preferably of at least 100 μm. The width of the opening is between 10 μm and 200 μm, for example. An opening having a diameter of at least 10 μm, preferably of at least 50 μm, and particularly preferably at least 100 μm, facilitates the application of the electrical connection layer. The electrical connection layer is preferably applied by an electrolytic method.

In accordance with at least one embodiment, the sidewalls of the opening run obliquely in such a way that a cross section of the opening increases proceeding from the carrier. The application of the electrical connection layer is simplified further in this way.

In accordance with at least one embodiment, a plurality of semiconductor chips are arranged on the carrier, wherein the electrically insulating layer at least partly fills the interspaces between the semiconductor chips. This advantageously makes it possible to form a first contacting plane at the level of the main surfaces of the semiconductor chips facing away from the carrier. A second contacting plane can be arranged at the level of the carrier and comprise for example conductor tracks on the carrier. The electrically insulating layer can advantageously at least partly planarize the interspaces between the semiconductor chips.

In accordance with at least one embodiment, the at least one semiconductor chip is an optoelectronic semiconductor chip. In this case, the semiconductor component is an optoelectronic semiconductor component. The at least one semiconductor chip can be in particular a light emitting diode chip. The main surface of the semiconductor chip facing away from the carrier can be in particular the radiation exit surface of a light emitting diode chip. A plurality of light emitting diode chips can be arranged on the carrier. In this case, the semiconductor component is a light emitting diode module or an LED display, for example.

Furthermore, a method for producing the semiconductor component is specified. In accordance with at least one embodiment, in the method a carrier is provided and at least one semiconductor chip is arranged on the carrier, wherein at least one first electrical contact of the semiconductor chips is arranged at a main surface facing away from the carrier. By way of example, the carrier has at least one conductor track, wherein a second electrical contact of the semiconductor chip, facing the carrier, is connected to the conductor track by an electrically conductive connection such as, for example, a solder layer or a conductive adhesive.

In accordance with at least one embodiment of the method, subsequently an electrically insulating layer is applied to the carrier, wherein the electrically insulating layer comprises a photopatternable material. By way of example, the electrically insulating layer can comprise a photoresist.

The electrically insulating layer is subsequently patterned photolithographically. In the case of a positive photoresist, the regions of the photoresist that are to be removed are exposed. Alternatively, in the case of a negative photoresist, the regions to be retained are exposed. The electrically insulating layer can be patterned for example in such a way that it forms a ramp from a plane of the carrier to a plane of the main surface of the at least one semiconductor chip facing away from the carrier. Alternatively or additionally, it is possible to produce one or a plurality of openings in the electrically insulating layer which run for example substantially vertically through the electrically insulating layer.

In accordance with at least one embodiment, in a further step, at least one electrical connection layer is applied to the electrically insulating layer, wherein the electrical connection layer is led to the first electrical contact by way of the electrically insulating layer. By way of example, the carrier has at least one conductor track, wherein the at least one electrical connection layer is led from the conductor track to the first electrical contact by way of the electrically insulating layer.

In accordance with at least one embodiment of the method, the electrically insulating layer is applied by a spray coating method. The electrically insulating layer is a flowable layer, in particular. By way of example, the electrically insulating layer is a photoresist that can be applied by means of a spray coating method. Application by a spray coating method has the advantage that different topography heights, for example in the case of a plurality of semiconductor chips having different heights that are arranged on the carrier, can easily be compensated for.

In accordance with at least one embodiment, applying the electrically insulating layer comprises applying and photolithographically patterning a first partial layer of the electrically insulating layer and subsequently applying and photolithographically patterning a second partial layer of the electrically insulating layer. The electrically insulating layer is supplied in two steps. During the application of the first partial layer, the majority of the material of the electrically insulating layer can be applied in this case. During the application of the second partial layer, a smaller portion of the material of the electrically insulating layer is applied over the first partial layer. In this case, the total thickness of the electrically insulating layer can be set very accurately during the application of the comparatively thinner second partial layer.

In accordance with at least one embodiment, during the process of applying and photolithographically patterning the first partial layer, a gap having a width of not more than 20 μm is produced between sidewalls of the semiconductor chip and the first partial layer, wherein the gap is filled with the second partial layer.

In this configuration, a covering of the chip edges of the semiconductor chip can be set very accurately. In particular, the risk of a bead of the material of the electrically insulating layer forming at the chip edge can advantageously be reduced. Such a bead would be disadvantageous for the subsequent application of the electrical connection layer.

In accordance with at least one embodiment, an opening is formed in the electrically insulating layer, wherein a part of the electrical connection layer is applied to sidewalls of the opening. The opening is advantageously produced photolithographically. Alternatively, the opening can be produced by laser beam drilling, for example.

In accordance with at least one embodiment, the electrical connection layer is produced electrolytically. The electrical connection layer is a copper layer, for example.

Further advantageous configurations of the method are evident from the description of the semiconductor component, and vice versa.

### BRIEF DESCRIPTION OF THE DRAWINGS

The invention is explained in greater detail below on the basis of exemplary embodiments in association with FIGS. 1 to 4.

In the figures:

FIG. 1 shows a schematic illustration of a cross section through one example of the semiconductor component,

FIG. 2 shows a schematic perspective illustration of a further example of the semiconductor component,

FIG. 3 shows a schematic illustration of a cross section through a further example of the semiconductor component, and

FIG. 4 shows a schematic illustration of a cross section through a further example of the semiconductor component.

### DETAILED DESCRIPTION OF ILLUSTRATIVE EMBODIMENTS

Identical or identically acting constituent parts are provided with the same reference signs in each case in the figures. The illustrated constituent parts and also the size relationships of the constituent parts among one another should not be regarded as true to scale.

FIG. 1 illustrates a first example of the semiconductor component 100. In the example, the semiconductor component 100 is an optoelectronic component, in particular an LED component. The semiconductor component 100 has a semiconductor chip 2, which is a light emitting diode chip. The semiconductor chip 2 has a semiconductor layer sequence 20 containing for example an n-type semiconductor region 21, a p-type semiconductor region 23 and an active layer 22 arranged between the n-type semiconductor region 21 and the p-type semiconductor region 23.

The active layer 22 can be in particular a radiation-emitting active layer. The active layer 22 can be formed for example as a pn junction, as a double heterostructure, as a single quantum well structure or a multiquantum well structure. In this case, the designation quantum well structure encompasses any structure in which charge carriers experience a quantization of their energy states as a result of confinement. In particular, the designation quantum well structure does not include any indication about the dimensionality of the quantization. It therefore encompasses, inter alia, quantum wells, quantum wires and quantum dots and any combination of these structures.

The n-type semiconductor region 21, the p-type semiconductor region 23 and the active layer 22 can each comprise one or a plurality of semiconductor layers. The n-type semiconductor region 21 contains one or a plurality of n-doped semiconductor layers and the p-type semiconductor region 23 contains one or a plurality of p-doped semiconductor layers. It is also possible for the n-type semiconductor region 21 and/or the p-type semiconductor region 23 to contain one or a plurality of undoped semiconductor layers.

In the example illustrated, the n-type semiconductor region 21 faces the carrier 1. However, the opposite polarity is also possible.

The semiconductor layer sequence 20 of the semiconductor chip is preferably based on a III-V compound semiconductor material, in particular on a nitride, phosphide or arsenide compound semiconductor material. By way of example, the semiconductor layer sequence can contain InₓAl_{y}Ga_{1-x-y}N, InₓAl_{y}Ga_{1-x-y}P or InₓAl_{y}Ga_{1-x-y}As, in each case where 0≤x≤1, 0≤y≤1 and x+y≤1. In this case, the III-V compound semiconductor material need not necessarily have a mathematically exact composition according to one of the above formulae. Rather, it can comprise one or a plurality of dopants and additional constituents. For the sake of simplicity, however, the above formulae include only the essential constituents of the crystal lattice, even if these can be replaced in part by small amounts of further substances.

The semiconductor chip 2 has a first electrical contact 11 at a side facing away from the carrier. A second electrical contact 12 can be arranged at the side of the semiconductor chip 2 facing the carrier 1 and is connected to a conductor track on the carrier 1, for example.

The semiconductor component 100 has a photopatternable electrically insulating layer 3, which is arranged on the carrier 1 and in particular adjoins the sidewalls of the semiconductor chip 2. During the production of the semiconductor component, the electrically insulating layer 3 is advantageously applied by a spray coating method. The electrically insulating layer 3 is a flowable layer, in particular. By way of example, the electrically insulating layer 3 is a photoresist layer. The photopatternable electrically insulating layer 3 can be patterned by exposure and subsequent development. In this way, for example, it is possible to produce one or a plurality of openings in the electrically insulating layer 3, in particular for contact feedthroughs.

The first electrical contact 11 at the side of the semiconductor chip 2 facing away from the carrier 1 is contacted by an electrical connection layer 4 led by way of the electrically insulating layer 3. In other words, the semiconductor chip 2 has a so-called planar contacting that is free of bond wires.

The electrically insulating layer 3 can have the form of a ramp that compensates for the height difference between a contacting plane at the level of the carrier 1, for example a conductor track 13 on the carrier 1, and the main surface of the semiconductor chip 2 facing away from the carrier 1. The electrically insulating layer 3 prevents in particular a short circuit at the sidewalls of the semiconductor chip 2. It is possible for a part of the electrically insulating layer 3 to cover a part of the main surface of the semiconductor chip 2 facing away from the carrier 1, in particular at the edge of the semiconductor chip 2. This prevents the electrical connection layer 4 from being led directly by way of the chip edge of the semiconductor chip 2.

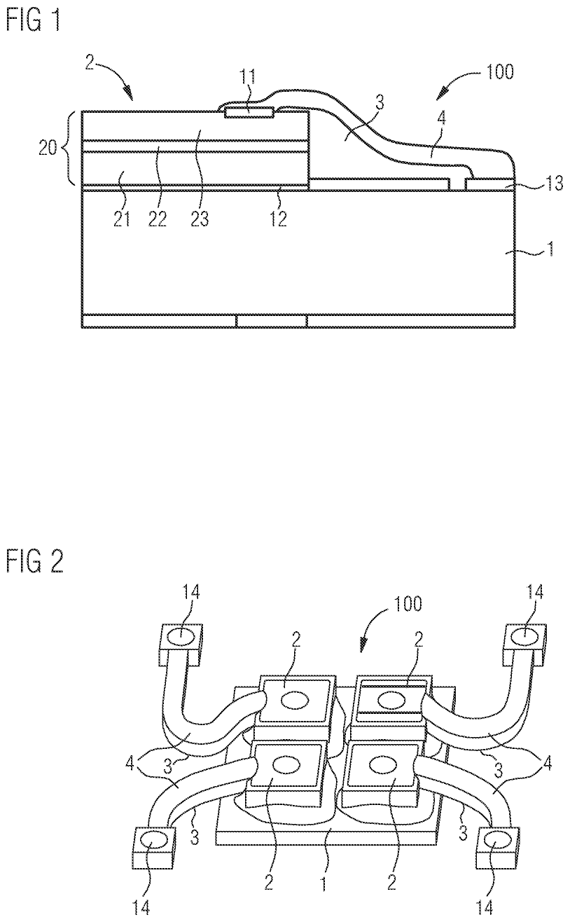

FIG. 2 illustrates a further example of the semiconductor component 100. The latter is a semiconductor component comprising a plurality of semiconductor chips 2. In the example illustrated, in particular four semiconductor chips 2 are arranged on a common carrier 1. The semiconductor component 100 can be an RGB light emitting diode component, in particular, in which the semiconductor chips 2 each comprise at least one semiconductor chip 2 for emitting the colors, red, green and blue. An additional green emitting semiconductor chip 2 or a semiconductor chip 2 that emits white light can be provided for example as fourth semiconductor chip 2. It is possible for the semiconductor chips 2 to form a pixel of an LED display.

In the example, a connection contact 14 at the level of the carrier 1 is provided for each of the semiconductor chips 2. The connection contacts 14 are each connected, by means of an electrical connection layer 4 led by way of an electrically insulating layer 3, to a first electrical contact at the main surface of the semiconductor chips 2 facing away from the carrier. In this case, the electrically insulating layer 3 is embodied as a ramp that compensates for the height difference between the connection contacts 14 and the top side of the semiconductor chips 2. As in the previous example, during production the electrically insulating layer 3 is applied by means of a spray coating method and is subsequently patterned photolithographically.

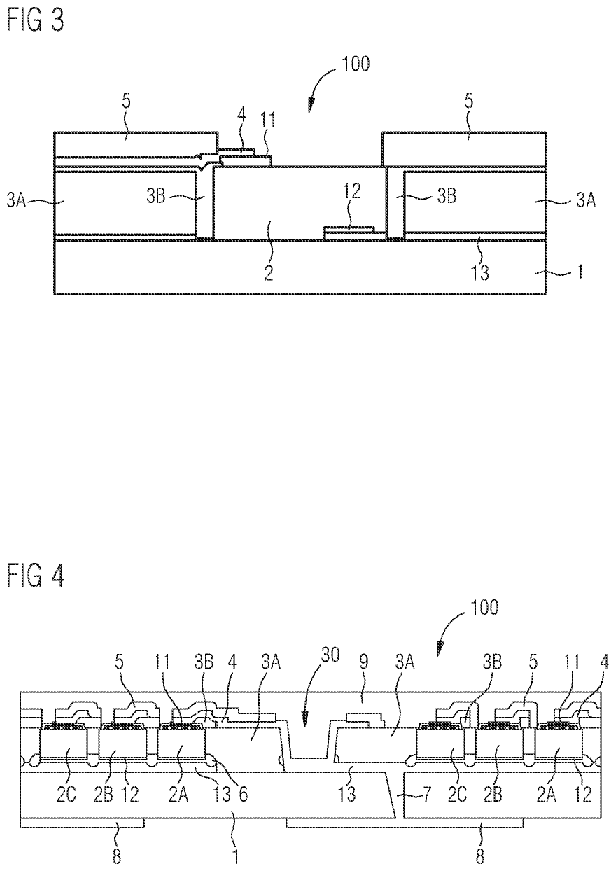

FIG. 3 illustrates a further example of the semiconductor component 100. The semiconductor component 100 has a semiconductor chip 2, which is a light emitting diode chip, for example. The semiconductor chip 2 has a first electrical contact 11 at a main surface facing away from the carrier 1, and a second electrical contact 12 at a main surface facing the carrier 1. The second electrical contact 12 is connected for example to a conductor track 13 arranged on the carrier 1. The first electrical contact 11 is connected to an electrical connection layer 4 led by way of an electrically insulating layer 3A, 3B. In this example, the electrically insulating layer 3A, 3B comprises a first partial layer 3A and a second partial layer 3B arranged thereover. Advantageously, both the first partial layer 3A and the second partial layer 3B are each photopatternable layers.

The two-part electrically insulating layer 3A, 3B is advantageously produced in a two-stage process in a method for producing the semiconductor component 100. In a first step, the first partial layer 3A is preferably applied by a spray coating method. The first partial layer 3A is subsequently patterned photolithographically. In the process a gap is produced between the sidewalls of the semiconductor chip 2 and the first partial layer 3A. The gap preferably has a width of between 5 μm and 20 μm.

In a second step, the second partial layer 3B is then applied over the first partial layer 3A, wherein the second partial layer 3B in particular fills the gap between the sidewalls of the semiconductor chip 2 and the first partial layer 3A. The second partial layer 3B, like the first partial layer 3A, is preferably applied by a spray coating method. The second partial layer 3B can be patterned photolithographically. It is possible for a part of the second partial layer 3B to cover a part of the main surface of the semiconductor chip 2 facing away from the carrier. In particular, a part of the second partial layer 3B can cover an upper chip edge of the semiconductor chip 2 in order to avoid in particular a contact between the surface of the semiconductor chip 2 and the electrical connection layer 4 at the chip edge.

The two-stage process for producing the two-part electrically insulating layer 3A, 3B in this example has the advantage, in particular, that only a small amount of the material of the electrically insulating layer has to be applied during the production of the second partial layer 3B. The amount of material to be applied is small in particular because only a narrow gap between the first partial layer 3A and the sidewalls of the semiconductor chip 2 has to be filled, the gap preferably having a width of only between 5 μm and 20 μm. Since only a small amount of material is applied with the second partial layer, the risk of a bead of the material of the electrically insulating layer forming at the chip edge can advantageously be reduced. Such a bead would be disadvantageous for the subsequent application of the electrical connection layer 4.

In a further step, a cover layer 5 can be applied to the electrical connection layer 4 and/or the electrically insulating layer 3A, 3B. The cover layer 5 is preferably an electrically insulating layer. The cover layer 5 can serve for example for protecting the electrical connection layer 4 against corrosion. Alternatively or additionally, the cover layer 5, if the semiconductor chip 2 is a light emitting diode chip, for example, can be used for enhancing contrast. In this case, the cover layer 5 is a layer composed of a black lacquer, for example. Regions of the optoelectronic component next to the radiation exit surface of the light emitting diode chip appear black in this case and have a high contrast with respect to the luminous radiation exit surface during operation of the semiconductor component.

FIG. 4 illustrates an excerpt from a further example of the semiconductor component 100 in cross section. In this case, the semiconductor component 100 is an LED display, in particular an RGB LED display. In the semiconductor component 100, groups of semiconductor chips 2A, 2B, 2C are arranged on a carrier 1. Each group comprises in particular a semiconductor chip 2A that emits red light, a semiconductor chip 2B that emits green light, and a semiconductor chip 2C that emits blue light. The groups of semiconductor chips each form a pixel of the LED display, for example.

The semiconductor chips 2A, 2B, 2C each have a first electrical contact 11 at a main surface facing away from the carrier, and a second electrical contact 12 at a main surface facing the carrier 1. The second electrical contacts 12 are connected to a conductor track 13 on the carrier 1 for example by a conductive adhesive 6 or alternatively by a solder layer. The carrier 1 can have one or a plurality of through contacts 7 in order to connect conductor tracks 13 at the top side of the carrier 1 to conductor tracks 8 at the underside of the carrier 1.

An electrically insulating layer 3A, 3B is arranged on the carrier 1. As in the previous example, the electrically insulating layer 3A, 3B comprises a first partial layer 3A and a second partial layer 3B. The first partial layer 3A of the electrically insulating layer preferably has a height which substantially corresponds to the height of the semiconductor chips 2. The first partial layer 3A can terminate in particular flush with the main surfaces of the semiconductor chips 2 facing away from the carrier 1. The first partial layer 3A fills in particular the interspaces between adjacent semiconductor chips 2. A second partial layer 3B is applied to the first partial layer 3A, and can cover in particular the chip edges of the semiconductor chips 2. The first partial layer 3A and the second partial layer 3B of the electrically insulating layer 3A, 3B are photopatternable layers which are in each case patterned photolithographically during the production of the semiconductor component 100. Furthermore, the first partial layer 3A and the second partial layer 3B are advantageously flowable layers in each case, which can be applied by a spray coating method.

The first electrical contacts 11 of the semiconductor chips 2 are each connected to an electrical connection layer 4 led by way of the electrically insulating layer 3A, 3B. The electrically insulating layer 3A, 3B has an opening 30. The electrical connection layer 4 is led to the conductor track 13 on the carrier 1 by way of sidewalls of the opening. An electrically conductive connection between a contacting plane at the level of the top side of the semiconductor chips 2 and a further contacting plane at the level of the carrier 1 is produced in this way.

The opening 30 in the electrically insulating layer preferably has a width of between 50 μm and 200 μm, for example approximately 100 μm. This approximately corresponds to the height of the semiconductor chips 2. The opening 30 preferably has an aspect ratio (height to width ratio) of not more than 2, preferably not more than 1. The opening 30 is advantageously produced photolithographically. Alternatively, the opening 30 in the electrically insulating layer 3A, 3B can be produced by laser beam drilling.

It is advantageous if the opening 30 has sidewalls that run obliquely in such a way that a cross section of the opening 30 increases proceeding from the carrier. This facilitates the production of the electrical connection layer 4 at the sidewalls of the opening 30. An opening 30 having such oblique sidewalls can be produced photolithographically by means of a suitable exposure or by means of laser beam drilling.

The electrical connection layer 4 is preferably produced electrolytically. During production, for example, firstly a seed layer is applied and the electrical connection layer 4 is subsequently deposited electrolytically. By way of example, the electrical connection layer 4 comprises copper or gold. These materials are distinguished by a good electrical conductivity, in particular. The electrical connection layer 4 can be patterned by methods known per se.

It is possible for a cover layer 5 to be applied to regions of the electrical connection layer 4 and/or of the electrically insulating layer 3A, 3B, said cover layer serving for example for protection against corrosion and/or for enhancing contrast. The cover layer 5 is a black protective lacquer, for example. Furthermore, a transparent enclosure 9 can be applied to the semiconductor component, for example a silicone potting. The transparent enclosure 9 serves in particular as a protective layer for the semiconductor component 100.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

1.-15. (canceled)

16. A semiconductor component comprising:
a carrier;
at least one semiconductor chip arranged on the carrier, the semiconductor chip having at least one first electrical contact at a main surface of the semiconductor chip facing away from the carrier;
an electrically insulating layer arranged on the carrier; and
at least one electrical connection layer led by the electrically insulating layer to the first electrical contact,
wherein the electrically insulating layer comprises a photopatternable material.

17. The semiconductor component as claimed in claim 16, wherein the photopatternable material is a flowable layer.

18. The semiconductor component as claimed in claim 16, wherein the at least one electrical connection layer is led from a plane of the carrier to the first electrical contact by the electrically insulating layer.

19. The semiconductor component as claimed in claim 16, wherein an opening is arranged in the electrically insulating layer, and wherein a part of the electrical connection layer is led by sidewalls of the opening.

20. The semiconductor component as claimed in claim 19, wherein the opening has a width of at least 10 μm.

21. The semiconductor component as claimed in claim 19, wherein the sidewalls of the opening run obliquely in such a way that a cross section of the opening increases proceeding from the carrier.

22. The semiconductor component as claimed in claim 16, wherein a plurality of semiconductor chips are arranged on the carrier, and wherein the electrically insulating layer at least partly fills interspaces between the semiconductor chips.

23. The semiconductor component as claimed in claim 16, wherein the at least one semiconductor chip is an optoelectronic semiconductor chip.

24. A method for producing a semiconductor component, the method comprising:
arranging at least one semiconductor chip on a carrier, wherein at least one first electrical contact of the semiconductor chip is arranged at a main surface of the semiconductor chip facing away from the carrier;
applying an electrically insulating layer to the carrier, wherein the electrically insulating layer comprises a photopatternable material;
photopatterning the electrically insulating layer; and
applying at least one electrical connection layer to the electrically insulating layer, wherein the electrical connection layer is led to the first electrical contact by the electrically insulating layer.

25. The method as claimed in claim 24, wherein the carrier has at least one conductor track, and wherein the at least one electrical connection layer is led from the conductor track to the first electrical contact by the electrically insulating layer.

26. The method as claimed in claim 24, wherein the electrically insulating layer is applied by a spray coating method.

27. The method as claimed in claim 24, wherein applying the electrically insulating layer comprises applying and photolithographically patterning a first partial layer and subsequently applying and photolithographically patterning a second partial layer.

28. The method as claimed in claim 27, wherein a gap is formed between sidewalls of the semiconductor chip and the first partial layer as a result of applying and photolithographically patterning the first partial layer, wherein the gap has a width of not more than 20 μm, and wherein the gap is filled with the second partial layer.

29. The method as claimed in claim 24, wherein an opening is formed in the electrically insulating layer, and wherein a part of the electrical connection layer is applied to sidewalls of the opening.

30. The method as claimed in claim 24, wherein the electrical connection layer is electrolytically produced.
